(19) United States
(12) Patent Application Publication
(10) Pub. No.: US 2026/0371773 A1
(43) Pub. Date: Nov. 19, 2026

(54) STACKED OPTICAL COUPLER

(71) Applicant: SHANGHAI YINXIN ELECTRONIC TECHNOLOGY CO., LTD., Shanghai (CN)

(72) Inventor: Zhaohui JIA, Shanghai (CN)

(21) Appl. No.: 19/309,126

(22) Filed: Aug. 25, 2025

(30) Foreign Application Priority Data
May 15, 2025 (CN) 202510628431.0

(51) Int. Cl. H10F 55/25; H10F 77/00

(52) U.S. Cl. CPC H10F 55/25; H10F 77/93

(57) ABSTRACT

The present invention provides a stacked optical coupler, comprising a light receiving device and a light emitting device arranged in a stacked manner along a longitudinal direction. The light emitting device has a planar structure, bonding pads of the light emitting device are disposed on a front surface of the light emitting device, and light generated by the light emitting device is emitted from a back surface of the light emitting device. The light emitting device is arranged above the light receiving device in an inversion manner, the back surface of the light emitting device faces the light receiving device. A dimension of the light receiving device along a left-right extending direction is greater than a dimension of the light emitting device along the left-right extending direction, and the bonding pads of the light receiving device are disposed on a same surface of the light receiving device.

### FIELD OF THE INVENTION

The present invention relates to the technical field of optical couplers, and in particular, to a stacked optical coupler, namely a device for optical coupling, transmission, and isolation.

### DESCRIPTION OF THE RELATED ART

An optoelectronic coupler (also referred to as an “optical coupler”) is a component that transmits electrical signals between two electrically isolated circuits or systems via optical (light) signals.

An existing optical coupler is shown in FIG. 1, which exhibits significant technical limitations in multiple aspects. These limitations not only restrict production efficiency but also affect the performance and reliability of the final product. First, during the manufacturing process of the optical coupler, the method of manually placing and flipping the lead frame (1a) is inefficient, and this operational approach is incompatible with current universal packaging processes, resulting in increased production costs and limited output. Additionally, the use of separate dual frames to complete wire bonding of the emitting and receiving devices respectively, followed by face-to-face alignment stacking, further increases process complexity. In particular, the process of filling transparent silicone resin (3a) between the light-emitting chip (4a) and the receiving chip (5a), due to its complex operational requirements, is also incompatible with standard packaging processes. This not only extends the production cycle but also reduces product consistency and reliability. Encapsulation resin (2a) is finally applied for overall encapsulation. Thus, the first type of optical coupler in the prior art faces issues such as insufficient coupling alignment accuracy, gap variations, and aging of silicone resin materials.

Another existing optical coupler is shown in FIG. 2, which similarly involves filling transparent silicone resin between the light-emitting chip and the receiving chip, and likewise faces issues such as coupling alignment inaccuracies, gap variations, and aging of the silicone resin, thereby affecting light transmission efficiency. Furthermore, the light-emitting chip (4a) and the receiving chip (5a) in FIG. 2 are arranged in a coplanar configuration, which is disadvantageous for miniaturization of the optical coupler and imposes certain limitations on the light-emitting area.

Another existing optical coupler is shown in FIG. 3, wherein a conventional light-emitting chip (4a) and a receiving chip (5a) each have electrodes formed on both front and back surfaces to constitute a vertical structure. The receiving chip (5a) is formed by an upper photodiode array (5a-1) and a lower MOSFET (5a-2). Although possessing certain advantages, due to its relatively large thickness and limited light-emitting area, it cannot meet the requirements of advanced packaging technologies such as CSP (Chip Scale Package) or flip-chip bonding. In particular, when connections need to be implemented via bottom-side wiring, such a design is disadvantageous for integrated packaging with other integrated circuits (ICs), thereby limiting its application scope. The photodiode array is referred to as PDA (Photo Diode Array).

### SUMMARY OF THE INVENTION

Based on the foregoing description, the present invention provides a stacked optical coupler, aiming to solve technical problems in the prior art such as low alignment accuracy of transceiver devices, limited transmission efficiency, and restricted application scope.

A stacked optical coupler, comprising a light receiving device and a light emitting device arranged in a stacked manner along a longitudinal direction, the light emitting device has a planar structure, bonding pads of the light emitting device are disposed on a front surface of the light emitting device, and light generated by the light emitting device is emitted from a back surface of the light emitting device;
the light emitting device is arranged above the light receiving device in an inversion manner, the back surface of the light emitting device faces the light receiving device;
a dimension of the light receiving device along a left-right extending direction is greater than a dimension of the light emitting device along the left-right extending direction;
the bonding pads of the light receiving device are disposed on a same surface of the light receiving device.

Furthermore, the light receiving device has a planar structure, and a light sensing layer of the light receiving device is adjacent to a front surface of the light receiving device;
the bonding pads of the light receiving device are all located on the front surface of the light receiving device;
the front surface of the light receiving device and the back surface of the light emitting device are opposed to each other.

Furthermore, the light receiving device has a planar structure, and a light sensing layer of the light receiving device is adjacent to a front surface of the light receiving device;
the bonding pads of the light receiving device are all located on the front surface of the light receiving device;
the back surface of the light receiving device and the back surface of the light emitting device are opposed to each other.

Furthermore, a contact plane of the light receiving device and the light emitting device are bonded together by an optical adhesive.

Furthermore, a transparent isolation medium layer is interposed between the light receiving device and the light emitting device.

Furthermore, a dimension of the transparent isolation medium layer in a horizontal direction is greater than a dimension of the light emitting device in the horizontal direction.

Furthermore, a dimension of the transparent isolation medium layer in a horizontal direction is greater than a dimension of the light receiving device in the horizontal direction.

Furthermore, when the back surface of the light receiving device and the back surface of the light emitting device are opposed to each other, an adapter substrate is disposed below the light receiving device, and adapter bonding pads are disposed on an upper surface of the adapter substrate;
the bonding pads disposed on the front surface of the light receiving device and the adapter bonding pads on the adapter substrate are interconnected by wires.

Furthermore, adapter circuits for the light receiving device or the light emitting device are fabricated on the transparent isolation medium layer.

Furthermore, a material of the transparent isolation medium layer is at least one of sapphire, glass, polyimide, epoxy resin, and silicone material.

The beneficial technical effects of the present invention are as follows: the optical coupler of the present invention adopts a stacked structure, the bonding pads of optical transceiver devices are disposed on the same surface to form a planar structure. Compared to the vertical structure of conventional transceiver chips, the thickness is reduced and the application scope is expanded. Manual placement and flipping of carriers are eliminated, and dispensing of intermediate transparent resin is not required. Process complexity is reduced, manufacturing costs are lowered, and light transmission efficiency is improved. The compact stacked structure with bonding pads on the same surface enables the use of universal packaging processes, such as standard lead frame processes, and facilitates the miniaturization of optical coupler devices. Additionally, it satisfies both signal coupling between the transmitter and receiver ends and isolation of safety voltages, while also offering the convenience of standard packaging with coplanar bonding pads.

### BRIEF DESCRIPTION OF THE DRAWINGS

FIGS. 1 to 3 are schematic structural diagrams of optical couplers in the prior art;

FIG. 4 is a schematic front-illuminated structural diagram of a stacked optical coupler according to the present invention;

FIG. 5 is a schematic back-illuminated structural diagram of a stacked optical coupler according to the present invention.

FIG. 6 is a schematic structural diagram of a front-illuminated stacked optical coupler combined with an adapter substrate according to the present invention.

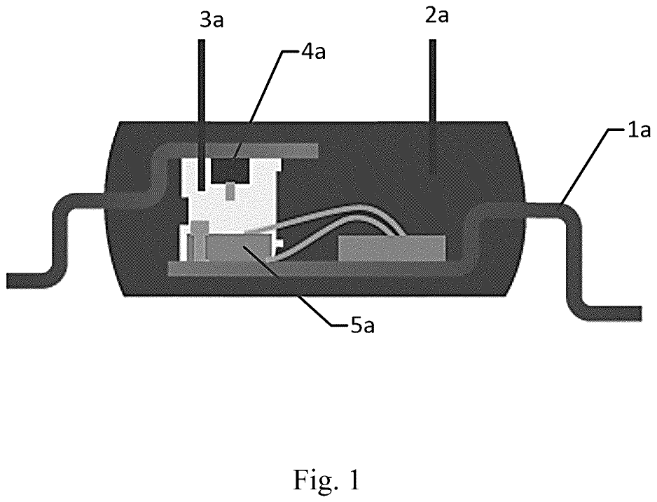

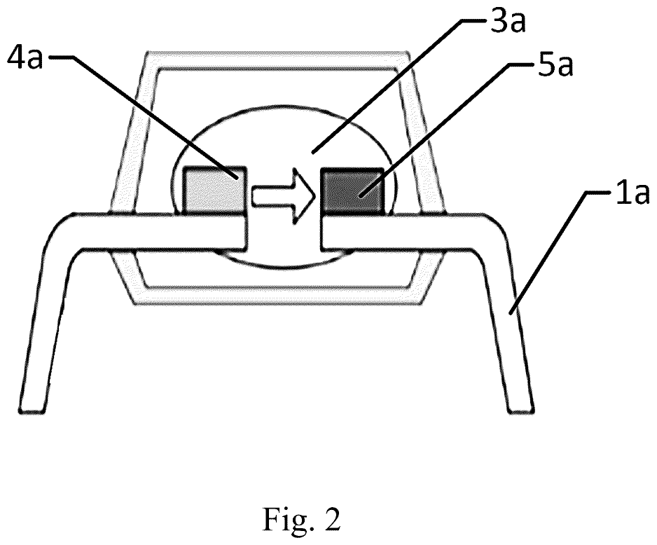

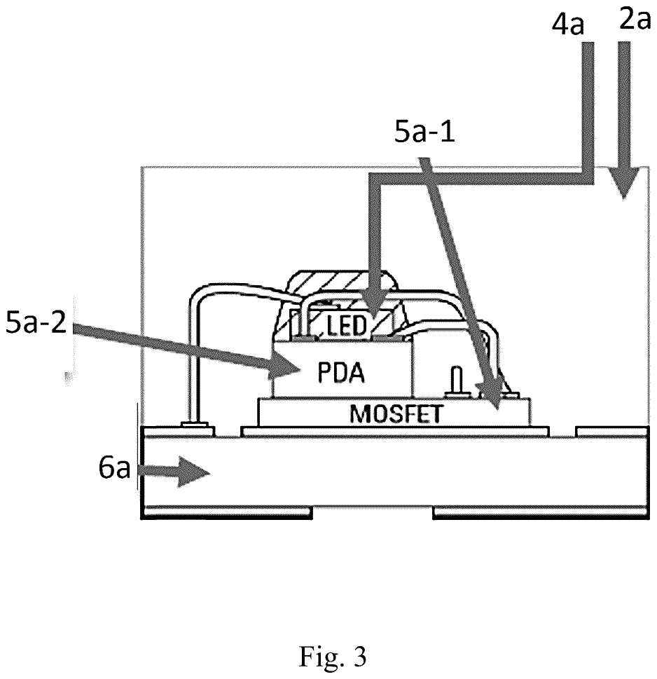

### CALL OUT LIST OF ELEMENTS

1—Light Emitting Device
1A—Lead Frame
2—Light Receiving Device
2A—Encapsulation Resin
3—Bonding Pads of the Light Emitting Device
3A—Transparent Silicone Resin
4—Bonding Pads of the Light Receiving Device
4A—Light-Emitting Chip
5—Optical Adhesive
5A—Receiving Chip
5A-1—Photodiode Array
5A-2—MOSFET
6—Transparent Isolation Medium Layer
6A—Substrate
7—adapter bonding pads
8—adapter substrate

### DETAILED DESCRIPTION

The technical solutions in the embodiments of the present invention will be clearly and completely described below in conjunction with the accompanying drawings in the embodiments of the present invention. It is apparent that the described embodiments are merely a part of the embodiments of the present invention, rather than all of them. All other embodiments obtained by a person of ordinary skill in the art based on the embodiments of the present invention without making creative efforts shall fall within the protection scope of the present invention.

It should be noted that, in the absence of conflict, the embodiments in the present invention and the features in the embodiments may be combined with each other.

The present invention will be further described below in conjunction with the accompanying drawings and specific embodiments, but such description shall not be construed as limiting the invention.

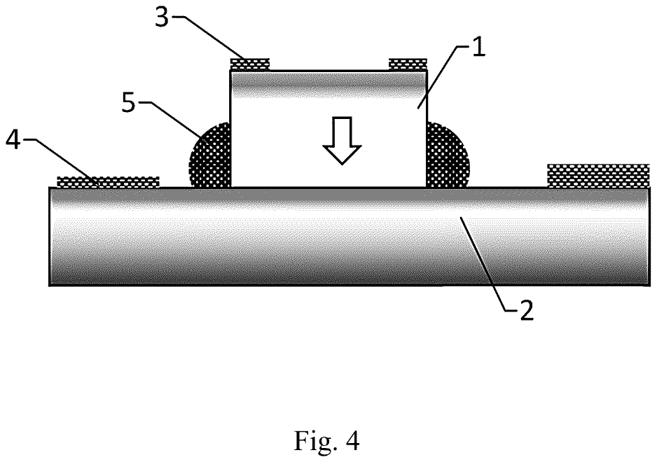

Referring to FIG. 4, a stacked optical coupler, comprising a light receiving device (2) and a light emitting device (1) arranged in a stacked manner along a longitudinal direction, the light emitting device (1) has a planar structure, bonding pads (3) of the light emitting device (1) are disposed on a front surface of the light emitting device (1), and light generated by the light emitting device (1) is emitted from a back surface of the light emitting device (1);
the light emitting device (1) is arranged above the light receiving device (2) in an inversion manner, the back surface of the light emitting device (1) faces the light receiving device (2);
a dimension of the light receiving device (2) along a left-right extending direction is greater than a dimension of the light emitting device (1) along the left-right extending direction;
the bonding pads (4) of the light receiving device (2) are disposed on a same surface of the light receiving device (2).

The optical coupler of the present invention adopts a stacked structure, the bonding pads of optical transceiver devices are disposed on the same surface to form a planar structure. Compared to the vertical structure of conventional transceiver chips, the thickness is reduced and the application scope is expanded. Manual placement and flipping of carriers are eliminated, and dispensing of intermediate transparent resin is not required. Process complexity is reduced, manufacturing costs are lowered, and light transmission efficiency is improved. The compact stacked structure with bonding pads on the same surface enables the use of universal packaging processes, such as standard lead frame processes, and facilitates the miniaturization of optical coupler devices. Additionally, it satisfies both signal coupling between the transmitter and receiver ends and isolation of safety voltages, while also offering the convenience of standard packaging with coplanar bonding pads.

Specifically, the light emitting device (1) faces a central region of the light receiving device (2) along a left-right extending direction.

Specifically, the light emitting device (1) has a planar structure, with positive and negative bonding pads disposed on the same surface. The light emitting device (1) may be fabricated using a suitable compound light-emitting device, and the light emission type may be a light-emitting diode (LED) or a laser. For example, in one embodiment, a GaN LED with a sapphire substrate may be employed, using sapphire as the substrate material and growing gallium nitride (GaN) to fabricate the light-emitting diode (LED). GaN is a wide-bandgap semiconductor material with excellent physical and chemical stability as well as superior electrical properties, while the sapphire substrate offers inherent advantages in high-voltage isolation. In the light emitting device of the present invention, the side where gallium nitride (GaN) is grown on the sapphire substrate may serve as the front surface, and the opposite side may serve as the back surface as the light-emitting side. Furthermore, in an embodiment, GaAs, which forms a planar structure, may also be used as the light emitting device (1).

The light emitting device (1) of the present invention adopts a flip-chip configuration, wherein light emitted from a light-emitting layer adjacent to the front surface is emitted from the back surface toward the light receiving device. Positive and negative bonding pads are disposed on the front surface, forming a planar structure rather than a vertical structure, resulting in a reduced thickness compared to the vertical structure. The planar structure, by eliminating the need for bonding pads on the back surface, enables a larger effective light-emitting area on the back surface. The reduced thickness of the planar structure facilitates miniaturization of the optical coupler device.

Additionally, the light receiving device (2) of the present invention similarly adopts a planar structure, with bonding pads for electrical connection to external circuits disposed on the same surface rather than in a vertical configuration, resulting in a reduced thickness compared to the vertical structure. This facilitates miniaturization of the optical coupler device.

The light receiving device (2) and the light emitting device (1) are arranged in a stacked manner, eliminating the need for dispensing transparent resin, thereby reducing the impact of aging issues on light transmission efficiency. This configuration also facilitates miniaturization, simplifies alignment between the two devices, improves coupling efficiency, reduces process variables, and streamlines manufacturing. Furthermore, the stacked arrangement is compatible with standard lead frame processes and enhances integration in co-packaging applications.

Furthermore, the light receiving device (2) has a planar structure, and a light sensing layer of the light receiving device (2) is adjacent to a front surface of the light receiving device (2);
the bonding pads of the light receiving device (2) are all located on the front surface of the light receiving device (2);
the front surface of the light receiving device (2) and the back surface of the light emitting device (1) are opposed to each other.

The light receiving device (2) similarly adopts a flip-chip configuration, specifically a planar flip-chip structure, wherein the side of the substrate with the light-sensing layer on the light receiving device serves as the front surface, and the opposite side of the substrate serves as the back surface.

Specifically, the light receiving device (2) may employ various photosensitive devices, including but not limited to: phototransistors, photoresistors, photovoltaic units and arrays thereof, as well as units or devices operating via photochemical or photoconductive modulation, such as colloidal or crystalline devices fabricated using materials including AgBr, AgO, ZnS, CdS, and the like. Photovoltaic units and arrays thereof, and phototransistor-type light receiving devices (2) may be fabricated using silicon-based or III-V group materials. For III-V group materials, GaN material may be utilized, wherein the quantum well structure of GaN material enables higher photonic quantum efficiency.

The light receiving device (2) has a planar structure, and a light sensing layer of the light receiving device (2) is adjacent to a front surface of the light receiving device (2);
the bonding pads of the light receiving device (2) are all located on the front surface of the light receiving device (2);
the back surface of the light receiving device (2) and the back surface of the light emitting device (1) are opposed to each other.

As an embodiment of the present invention, for example in FIG. 4, the front surface of the light receiving device (2) and the back surface of the light emitting device (1) are opposed to each other, forming a front-illuminated structure.

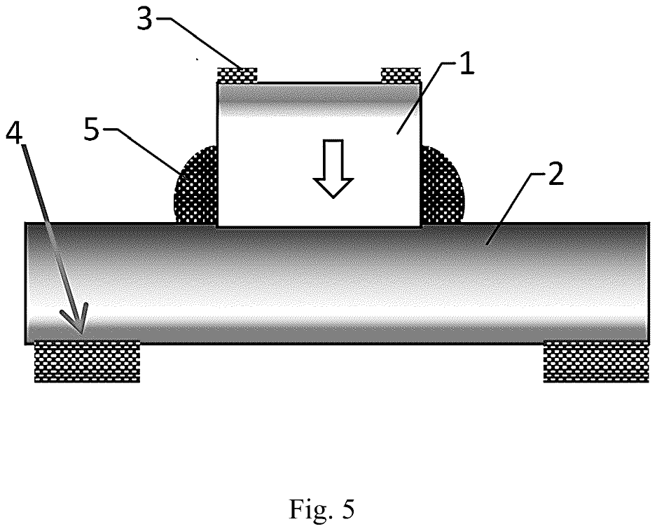

As another embodiment of the present invention, for example in FIG. 5, the back surface of the light receiving device (2) and the back surface of the light emitting device (1) are opposed to each other, forming a back-illuminated structure. Such a configuration provides improved optical coupling efficiency.

Furthermore, a contact plane of the light receiving device (2) and the light emitting device (1) are bonded together by an optical adhesive (5). By directly bonding the light emitting device (1) and the light receiving device (2) in a surface-contact stacked manner through such optical adhesive bonding, the manufacturing process is simplified compared to conventional optical coupler fabrication methods, alignment is facilitated, production costs are reduced, light transmission efficiency is improved, and the performance of the optical coupler device is enhanced.

Specifically, based on actual design requirements, the light emitting device (1) may be oriented toward a central region of the light receiving device (2) along the left-right extending direction. The bonding pads (3) of the light emitting device (1) are disposed at left and right edge regions of the front surface of the light emitting device (1), and the bonding pads (4) of the light receiving device (2) are disposed at left and right edge regions of the front surface of the light receiving device (2).

Furthermore, a transparent isolation medium layer (6) is interposed between the light receiving device (2) and the light emitting device (1).

Light emitted from the light emitting device (1) passes through the transparent isolation medium layer (6) and enters the light receiving device (2).

The transparent isolation medium layer (6) may further physically separate circuits on the input side and the output side, enhancing electrical isolation performance and preventing current leakage or interference.

Specifically, the thickness of the transparent isolation medium layer (6) ranges from 50 micrometers to 1 millimeter.

Furthermore, a dimension of the transparent isolation medium layer (6) in a horizontal direction is greater than a dimension of the light emitting device in the horizontal direction.

Furthermore, a dimension of the transparent isolation medium layer (6) in a horizontal direction is greater than a dimension of the light receiving device in the horizontal direction.

Furthermore, when the back surface of the light receiving device (2) and the back surface of the light emitting device (1) are opposed to each other, an adapter substrate (8) is disposed below the light receiving device (2), and adapter bonding pads (7) are disposed on an upper surface of the adapter substrate (8);
the bonding pads disposed on the front surface of the light receiving device (2) and the adapter bonding pads (7) on the adapter substrate (8) are interconnected by wires.

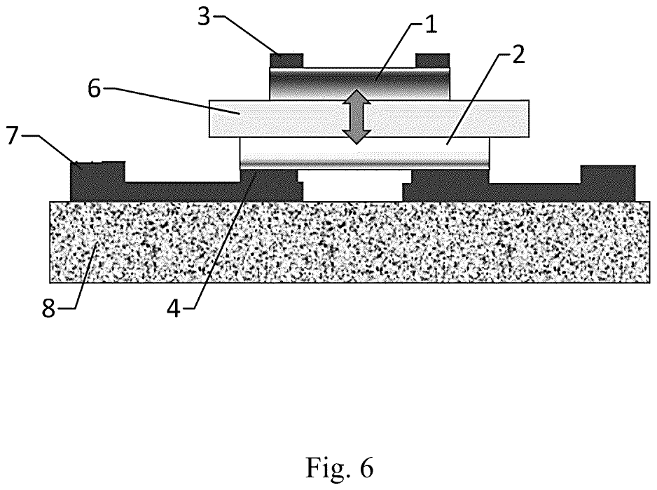

Referring to FIG. 6, in another embodiment of the present invention, for example in FIG. 5, on the basis of the back-illuminated structure, an adapter substrate and adapter bonding pads are further added. The originally downward-facing bonding pads of the light receiving device can be converted into upward-facing adapter bonding pads, which facilitates subsequent universal standard lead frame processes and universal packaging processes, and is conducive to co-packaging with other chip ICs.

Furthermore, adapter circuits for the light receiving device or the light emitting device are fabricated on the transparent isolation medium layer (6).

That is, the transparent isolation medium layer can serve not only as an optical path but also as an interposer for circuit interconnection, thereby saving material usage in the optical coupler and reducing unnecessary waste.

The interconnection circuits on the interposer are fabricated using patterning processes (e.g., PVD, photolithography, etching, etc.).

Furthermore, a material of the transparent isolation medium layer (6) is at least one of sapphire, glass, polyimide, epoxy resin, and silicone material.

The foregoing describes only preferred embodiments of the invention, which therefore do not limit its embodiments or scope of protection. Those skilled in the art should recognize that all solutions obtained through equivalent substitutions or obvious modifications based on the specification and drawings of this invention shall fall within its protective scope.

1. A stacked optical coupler, comprising a light receiving device and a light emitting device arranged in a stacked manner along a longitudinal direction, the light emitting device has a planar structure, bonding pads of the light emitting device are disposed on a front surface of the light emitting device, and light generated by the light emitting device is emitted from a back surface of the light emitting device;
the light emitting device is arranged above the light receiving device in an inversion manner, the back surface of the light emitting device faces the light receiving device;
a dimension of the light receiving device along a left-right extending direction is greater than a dimension of the light emitting device along the left-right extending direction;
the bonding pads of the light receiving device are disposed on a same surface of the light receiving device.

2. The stacked optical coupler of claim 1, wherein the light receiving device has a planar structure, and a light sensing layer of the light receiving device is adjacent to a front surface of the light receiving device;
the bonding pads of the light receiving device are all located on the front surface of the light receiving device;
the front surface of the light receiving device and the back surface of the light emitting device are opposed to each other.

3. The stacked optical coupler of claim 1, wherein the light receiving device has a planar structure, and a light sensing layer of the light receiving device is adjacent to a front surface of the light receiving device;
the bonding pads of the light receiving device are all located on the front surface of the light receiving device;
the back surface of the light receiving device and the back surface of the light emitting device are opposed to each other.

4. The stacked optical coupler of claim 1, wherein a contact plane of the light receiving device and the light emitting device are bonded together by an optical adhesive.

5. The stacked optical coupler of claim 1, wherein a transparent isolation medium layer is interposed between the light receiving device and the light emitting device.

6. The stacked optical coupler of claim 5, wherein a dimension of the transparent isolation medium layer in a horizontal direction is greater than a dimension of the light emitting device in the horizontal direction.

7. The stacked optical coupler of claim 5, wherein a dimension of the transparent isolation medium layer in a horizontal direction is greater than a dimension of the light receiving device in the horizontal direction.

8. The stacked optical coupler of claim 3, wherein when the back surface of the light receiving device and the back surface of the light emitting device are opposed to each other, an adapter substrate is disposed below the light receiving device, and adapter bonding pads are disposed on an upper surface of the adapter substrate;
the bonding pads disposed on the front surface of the light receiving device and the adapter bonding pads on the adapter substrate are interconnected by wires.

9. The stacked optical coupler of claim 7, wherein adapter circuits for the light receiving device or the light emitting device are fabricated on the transparent isolation medium layer.

10. The stacked optical coupler of claim 5, wherein a material of the transparent isolation medium layer is at least one of sapphire, glass, polyimide, epoxy resin, and silicone material.
